(19) United States
(12) Patent Application Publication
(10) Pub. No.: US 2003/0054629 A1
(43) Pub. Date: Mar. 20, 2003

(54) Semiconductor device and manufacturing method thereof

(75) Inventors: Kenji Kawai, Hyogo (JP); Kenichiro Shiozawa, Hyogo (JP); Yusuke Nakajima, Hyogo (JP)

Correspondence Address: McDERMOTT, WILL & EMERY, 600 13th Street, N.W., Washington, DC, 20005-3096, US

(73) Assignee: Mitsubishi Denki Kabushiki Kaisha

(21) Appl. No.: 10/144,927

(22) Filed: May 15, 2002

(30) Foreign Application Priority Data
Sep. 18, 2001 (JP) 2001-283327(P)

(51) Int. Cl. H01L 21/4763

(52) U.S. Cl. 438/622; 438/638; 438/636

(57) ABSTRACT

A first interconnection is formed in a first interlayer insulating film. An etching stopper film is formed on the first interconnection. On the etching stopper film, a second interlayer insulating film and an anti-reflective coating are successively formed, and a via hole penetrating the second interlayer insulating film and the anti-reflective coating to reach the etching stopper film is formed. An organic film is formed in the via hole, and a trench reaching the organic film is formed in the second insulating film. By removing the anti-reflective coating and the etching stopper film at the bottom portion of the via hole, a portion of the surface of the first interconnection is exposed, and a second interconnection is formed in the trench and the via hole.

### BACKGROUND OF THE INVENTION

1. Field of the Invention

The present invention relates to a semiconductor device having a dual damascene structure and a manufacturing method thereof.

2. Description of the Background Art

FIGS. 10A to 10F show a process flow of a semiconductor device having a conventional dual damascene structure. The dual damascene structure as used herein represents a structure in which an insulating film is etched to integrate a trench for interconnection with a via hole for interlayer conduction, and an interconnection material is then embedded therein respectively through damascene process.

As shown in FIG. 10A, a second interlayer insulating film 3, an anti-reflective coating 4 and a photoresist 5 are formed on a first interconnection 2 formed within a first interlayer insulating film 1. Photoresist 5 is patterned to a prescribed shape, and using this photoresist 5 as a mask, etching is performed to form a via hole 6.

The surface of first interconnection 2 is thus exposed. Through etching to form via hole 6, however, a subtrench (a semi-spheric portion) 7 is formed in the bottom portion of via hole 6, as shown in FIG. 10A. Subtrench 7 will be made larger when overetching in forming via hole 6 is extended.

As shown in FIG. 10B, photoresist 5 is then removed with O₂ plasma. Here, as the surface of first interconnection 2 is exposed, O₂ plasma oxidizes and alters the same to form an altered layer 8 thereon.

A photoresist 9 is formed on anti-reflective coating 4 and patterned to a prescribed shape. By etching using this photoresist 9 as a mask, a trench 10 is formed as shown in FIG. 10C. Here again, a subtrench 11 is formed in the bottom portion of trench 10, while subtrench 7 in the bottom portion of via hole 6 is made larger.

As shown in FIG. 10D, photoresist 9 is then removed with O₂ plasma, and by exposure thereto, the surface of first interconnection 2 is further altered. Thereafter, as shown in FIG. 10E, whole surface is etched to remove anti-reflective coating 4. With this etching of the whole surface, subtrenches 7, 11 are further made larger.

Next, a barrier layer 12 and a second interconnection 13 are formed within trench 10 and via hole 7, and the surface thereof is planarized with CMP (Chemical Mechanical Polishing) as shown in Fig. 10F.

As described above, when altered layer 8 is formed on the surface of first interconnection 2, connection and adhesion properties with second interconnection 13 is deteriorated and resistance is increased. In addition, when subtrenches 7, 11 are formed, embedding of barrier layer 12 would be less satisfactory and voids 14 and 15 are formed, leading to a defect. Moreover, as shown in FIG. 10F, because of the unsatisfactory embedding of barrier layer 12, a defect may result between first and second interconnections 2, 13 due to disconnection thereof in a region 24.

Japanese Patent Laying-Open Nos. 2001-102449, 2000-150644 and 2000-208620 describe inventions for improving aforementioned conventional arts.

In an invention described in Japanese Patent Laying-Open No. 2001-102449, a photoresist is left on the bottom of a hole simultaneously with formation of a photoresist for trench formation. Accordingly, it is difficult to adjust the height of the photoresist left on the bottom of the hole.

In an invention described in Japanese Patent Laying-Open No. 2000-150644, after exposing a lower interconnection while photoresist still remains, ashing is performed. Therefore, the surface of the lower interconnection is altered to increase resistance.

In an invention described in Japanese Patent Laying-Open No. 2000-208620, an anti-reflective coating is not formed when a hole for connection hole is formed. Therefore, dimension accuracy of the hole is lowered.

### SUMMARY OF THE INVENTION

The present invention has been made to solve the above-mentioned problems. An object of the present invention is to form a protective film on the bottom of a via hole in a stable manner and to suppress lowering of dimension accuracy of the via hole, while suppressing generation of a subtrench and alteration of the surface of a first interconnection.

In one aspect, a method of manufacturing a semiconductor device according to the present invention includes the steps of: forming a first interconnection within a first interlayer insulating film; forming an etching stopper film on the first interconnection; successively forming a second interlayer insulating film and an anti-reflective coating on the etching stopper film; forming a via hole penetrating the second interlayer insulating film and the anti-reflective coating to reach the etching stopper film; forming a protective film in the via hole; forming a trench reaching the protective film in the second interlayer insulating film; exposing a portion of a surface of the first interconnection by removing the anti-reflective coating and the etching stopper film on a bottom portion of the via hole; and forming a second interconnection within the trench and the via hole.

As described above, since the etching stopper film is formed on the first interconnection, etching can be stopped at the etching stopper film in forming a via hole and the first interconnection can be prevented from being exposed at the bottom of the via hole. Formation of a subtrench at the bottom of the via hole can also be avoided. In addition, formation of a protective film composed of an organic film and the like in the via hole can protect the bottom of the via hole and the etching stopper film. Here, by forming a mask for trench formation and a protective film in different steps, the height of the protective film from the bottom of the via hole can be adjusted easily. Moreover, formation of an anti-reflective coating on the second interlayer insulating film can also suppress lowering of dimension accuracy of the via hole.

The second interlayer insulating film preferably includes an upper interlayer insulating film and a lower interlayer insulating film. Here, the step of forming the second interlayer insulating film includes the step of forming the upper interlayer insulating film on the lower interlayer insulating film.

Thus by constituting the second interlayer insulating film with a plurality of interlayer insulating films, etching for forming a trench is stopped at the boundary of interlayer insulating films, and formation of a subtrench on the bottom portion of the trench can be avoided.

An upper layer etching stopper film is preferably provided between the upper interlayer insulating film and the lower interlayer insulating film. In this case, the step of forming the second interlayer insulating film includes the step of forming the upper interlayer insulating film on the lower interlayer insulating film, with the upper layer etching stopper film interposed. The step of forming the trench includes the step of stopping etching at the upper layer etching stopper film.

Thus by providing an upper layer etching stopper film, etching can be stopped at the upper layer etching stopper film in forming a trench. Accordingly, formation of a subtrench in the bottom portion of the trench can be avoided.

The upper interlayer insulating film and the lower interlayer insulating film may be composed of different materials. In this case, the step of forming the trench includes the step of forming the trench in the upper interlayer insulating film by stopping etching at the lower interlayer insulating film.

Thus by composing the upper interlayer insulating film and the lower interlayer insulating film of different materials, etching is stopped at the lower interlayer insulating film when forming a trench. In this case as well, formation of a subtrench in the bottom portion of the trench can be avoided. In particular, it is effective to select materials for the upper layer and lower interlayer insulating films in such a manner that etching rate of the lower interlayer insulating film is lower than that of the upper interlayer insulating film.

The step of forming the trench preferably includes the step of isotropically etching the second interlayer insulating film. Accordingly, a trench having a wall surface gently inclined from the upper surface of the second interlayer insulating film toward the via hole and having an edge slightly rounded can be formed, and formation of a subtrench in the bottom portion of the trench can be suppressed.

The isotropic etching may be performed by dry etching under the pressure not smaller than 1.33 Pa and not larger than 26.6 Pa. Accordingly, a trench with an above-described shape can be formed and formation of a subtrench in the bottom portion of the trench can be suppressed.

The step of forming the trench preferably includes the step of anisotropic etching after isotropic etching. In this case as well, by isotropic etching in advance, formation of a subtrench in the bottom portion of the trench can be suppressed.

The step of forming the second interconnection preferably includes the step of forming a tapered portion at upper end corner portions of the trench and the via hole. Accordingly, embedment property of the second interconnection can be improved.

The step of forming the protective film preferably includes the steps of applying a photoresist to the whole surface after the via hole is formed, and leaving the photoresist in the via hole by etching the same. The step of forming the protective film may also include the steps of applying a photoresist to the whole surface after the via hole is formed, and performing exposure and development of the photoresist to leave the same in the via hole.

As described above, by forming a protective film in a step different from the one for a mask for via hole formation, the height of the protective film from the bottom of the via hole can be adjusted easily.

In another aspect, a method of manufacturing a semiconductor device according to the present invention includes the steps of: forming a first interconnection within a first interlayer insulating film; forming an etching stopper film on the first interconnection; successively forming a second interlayer insulating film and an anti-reflective coating on the etching stopper film; forming a trench by isotropically etching the second interlayer insulating film; forming a via hole below the trench so as to reach the etching stopper film; exposing a portion of a surface of the first interconnection by removing the anti-reflective coating and the etching stopper film on a bottom portion of the via hole; and forming a second interconnection within the trench and the via hole.

As described above, by forming a via hole after a trench is formed, the step of forming a protective film in the via hole can be omitted, to simplify a process.

A semiconductor device according to the present invention has an interconnection structure manufactured with the method according to any of the aspects described above. Thus, a semiconductor device of high reliability and performance can be obtained.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIGS. 1A to 1F are cross-sectional views showing first to sixth steps in a manufacturing process of a semiconductor device in Embodiment 1 of the present invention.

FIGS. 2A to 2F are cross-sectional views showing first to sixth steps in a manufacturing process of a semiconductor device in Embodiment 2 of the present invention.

FIGS. 3A to 3F are cross-sectional views showing first to sixth steps in a manufacturing process of a semiconductor device in Embodiment 3 of the present invention.

FIGS. 4A to 4F are cross-sectional views showing first to sixth steps in a manufacturing process of a semiconductor device in Embodiment 4 of the present invention.

FIGS. 5A and 5B are cross-sectional views showing characteristic steps of a first variation of the manufacturing method of the semiconductor device in Embodiment 4 of the present invention.

FIGS. 6A and 6B are cross-sectional views showing characteristic steps of a second variation of the manufacturing method of the semiconductor device in Embodiment 4 of the present invention.

FIGS. 7A to 7F are cross-sectional views showing first to sixth steps of a manufacturing process of a semiconductor device in Embodiment 5 of the present invention.

FIG. 8 is a cross-sectional view showing a seventh step in the manufacturing process of the semiconductor device in Embodiment 5 of the present invention, and showing a semiconductor device in Embodiment 5.

FIG. 9 is a cross-sectional view showing a characteristic step of a variation of the manufacturing method of the semiconductor device in Embodiment 5 of the present invention.

FIGS. 10A to 10F are cross-sectional views showing first to sixth steps in a manufacturing process of a conventional semiconductor device.

### DESCRIPTION OF THE PREFERRED EMBODIMENTS

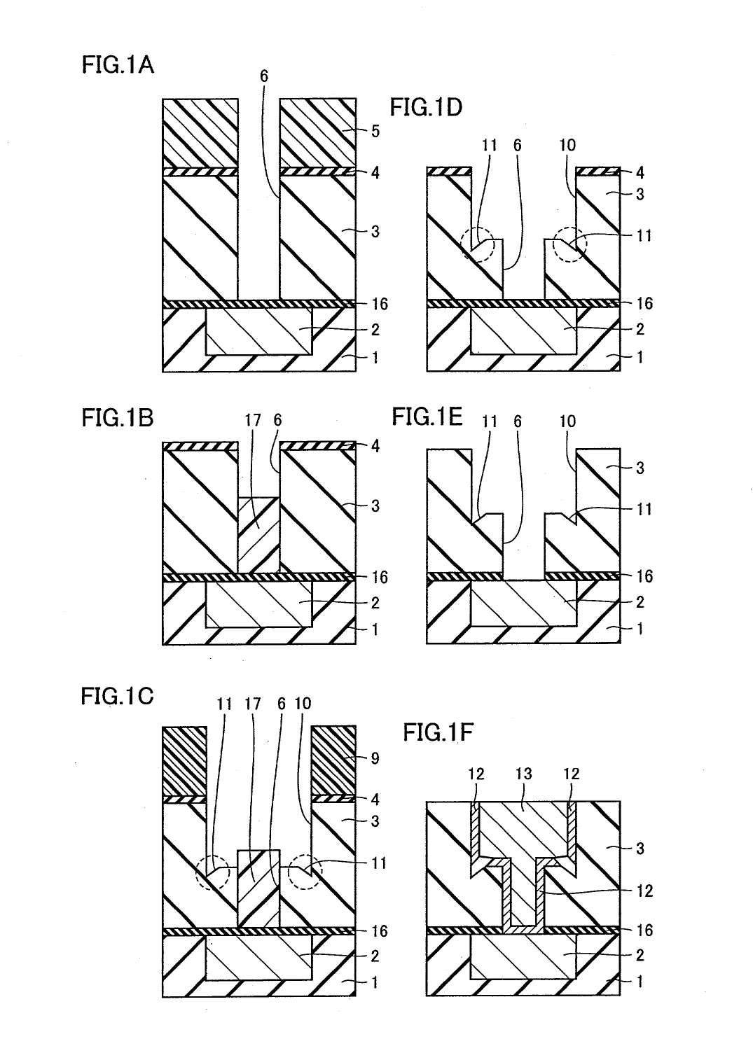

In the following, embodiments of the present invention will be described with reference to FIGS. 1 to 9.

### Embodiment 1

FIGS. 1A to 1F are cross-sectional views showing first to sixth steps in a manufacturing process of a semiconductor device in Embodiment 1 of the present invention.

As shown in FIG. 1A, a trench is formed in a first interlayer insulating film 1, and a first interconnection 2 is embedded in the trench. First interconnection 2 is composed of Cu, Ag, Au, Pt or the like. An etching stopper film 16 is formed so as to cover first interconnection 2. Etching stopper film 16 is composed of, for example, SiN or SiC, has a thickness of approximately 20 nm˜150 nm, and can be formed with CVD (Chemical Vapor Deposition) or the like.

A second interlayer insulating film 3 is formed on etching stopper film 16 with CVD and the like. Second interlayer insulating film 3 is preferably constituted of an insulating film of low dielectric constants. For example, a silicon-oxide-based film of low dielectric constants (SiOC, SiOF) can be adopted.

An anti-reflective coating 4 is formed on second interlayer insulating film 3. An inorganic anti-reflective coating such as plasma CVD-SiN or plasma CVD-SiON is preferably used rather than a carbon-based organic anti-reflective coating, because the former is readily etched under etching conditions close to those for second interlayer insulating film 3.

A photoresist 5 is applied on anti-reflective coating 4 and patterned to a prescribed shape. Using patterned photoresist 5 as a mask, dry etching such as RIE (Reactive Ion Etching) is performed to etch anti-reflective coating 4 and second interlayer insulating film 3. Etching is stopped at etching stopper film 16.

Thus a via hole 6 is formed. Here, as etching stopper film 16 still remains on the bottom portion of via hole 6, formation of a subtrench therein can be suppressed. As anti-reflective coating 4 has also been formed, dimension accuracy of via hole 6 can be improved.

Photoresist 5 is then removed with O₂ plasma. Here, as etching stopper film 16 still remains on the bottom portion of via hole 6, the surface of first interconnection 2 will not be altered. Preferably, however, etching stopper film 16 is composed of a film of low dielectric constants because capacitance between interconnections is produced thereby. In this viewpoint, SiC of a thickness of approximately 20 nm˜150 nm is preferably adopted as etching stopper film 16.

An organic film such as a photoresist is then applied to the whole surface, on which whole surface etching will be performed. Thus, as shown in FIG. 1B, an organic film (a protective film) 17 is embedded in via hole 6. Alternatively, a photoresist may be applied to the whole surface, exposed to an adjusted amount of exposure and then developed. With this method as well, organic film 17 can be embedded in via hole 6. Thus by embedding organic film 17 in via hole 6, the height of organic film 17 from the bottom portion of via hole 6 can be adjusted easily.

Next, a photoresist 9 is applied on anti-reflective coating 4 and patterned to a prescribed shape. Using patterned photoresist 9 as a mask, anti-reflective coating 4 and second interlayer insulating film 3 are etched. As shown in FIG. 1C, a trench 10 reaching organic film 17 is formed.

Here, though a subtrench 11 is formed in the bottom portion of trench 10, the surface of first interconnection 2 will not be exposed because of the presence of organic film 17 on the bottom portion of via hole 6. Formation of a subtrench in etching stopper film 16 can also be suppressed.

The bottom surface of trench 10 is preferably as high as the top surface of organic film 17, however, it is difficult to control the height of the latter. In order to surely prevent the diameter of via hole 6 from being enlarged, the height of the top surface of organic film 17 or the height of the bottom surface of trench 10 is adjusted so that the position of the former will be higher than that of the latter.

As shown in FIG. 1D, photoresist 9 is then removed, and at the same time, organic film 17 is also removed.

As shown in FIG. 1E, the whole surface is then etched to remove anti-reflective coating 4 and etching stopper film 16. Accordingly, a portion of the surface of first interconnection 2 is exposed. Here, if film thickness of anti-reflective coating 4 and etching stopper film 16 is adjusted in accordance with their respective etching rate, the amount of thinning of second interlayer insulating film 3 and first interconnection 2 can be controlled.

Though a subtrench is enlarged to some degree through above etching, formation thereof at the bottom portion of via hole 6 can be suppressed because of the presence of etching stopper film 16. In addition, in above etching, in order to selectively remove etching stopper film 16 with respect to second interlayer insulating film 3, the amount of O₂ added to etching gas is increased so that O₂ flow rate will account for 10% or larger with respect to fluorocarbon-based or hydrofluorocarbon-based gases.

Next, with sputtering method or CVD, a barrier layer 12 and a second interconnection 13 are formed. Ta/TaN can be used for barrier layer 12, and Cu can be used for second interconnection 13. Thereafter, barrier layer 12 and second interconnection 13 are polished with CMP, so that surfaces thereof are planarized as shown in FIG. 1F. Through those steps described above, a dual damascene structure shown in FIG. 1F can be obtained.

As described above, by forming etching stopper film 16 and organic film 17 on the bottom portion of via hole 6, a time period for plasma irradiation to the surface of first interconnection 2 can be shortened, and alteration of the surface thereof and generation of a subtrench can be suppressed. In addition, alteration of the surface of first interconnection 2 due to oxidization can also be suppressed since the surface thereof is not exposed to O₂ plasma in ashing.

Thus, an increase of resistance and a failure due to disconnection between first interconnection 2 and second interconnection 13 are suppressed, and a semiconductor device of high reliability, having a dual damascene structure, can be obtained.

### Embodiment 2

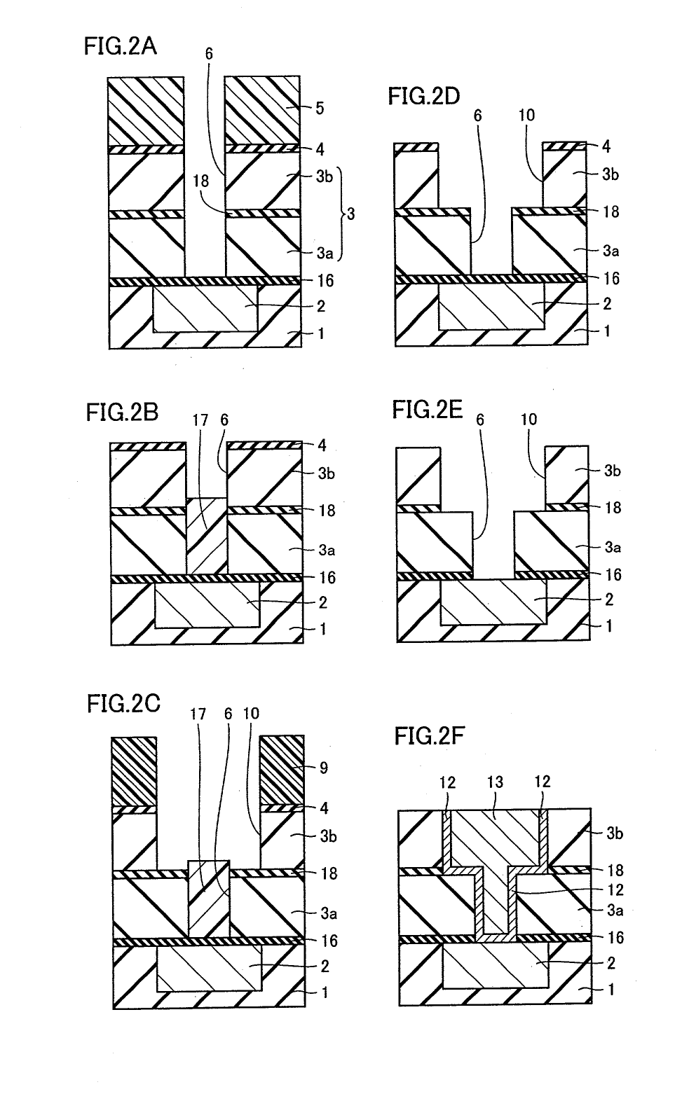

Next, Embodiment 2 of the present invention will be described with reference to FIGS. 2A to 2F. FIGS. 2A to 2F are cross-sectional views showing first to sixth steps in a manufacturing process of a semiconductor device in Embodiment 2.

In Embodiment 2, second interlayer insulating film 3 is constituted of a plurality of insulating films, between which an etching stopper film is formed. Other configurations are the same as in Embodiment 1.

As shown in FIG. 2A, structures up to etching stopper film 16 are formed with the same method as in Embodiment 1, and a lower interlayer insulating film 3a is then formed thereon with CVD or the like. A material for lower interlayer insulating film 3a may be the same as that for second interlayer insulating film 3 in Embodiment 1.

An upper layer etching stopper film 18 is formed on lower interlayer insulating film 3a with CVD or the like. A material for upper layer etching stopper film 18 may be the same as that for etching stopper film 16 in Embodiment 1.

An upper interlayer insulating film 3b is formed on upper layer etching stopper film 18 with CVD or the like. A material for upper interlayer insulating film 3b may be the same as that for lower interlayer insulating film 3a. Preferably, upper interlayer insulating film 3b is of a thickness, for example, of 350 nm to 120 nm and is one to four times as thick as lower interlayer insulating film 3a.

Anti-reflective coating 4 and photoresist 5 are formed on upper interlayer insulating film 3b with the same method as in Embodiment 1. Using photoresist 5 as a mask, etching is performed to form via hole 6 reaching etching stopper film 16, as shown in FIG. 2A.

Thereafter, as shown in FIG. 2B, with the same method as in Embodiment 1, organic film 17 is formed and photoresist 9 is formed on anti-reflective coating 4. Using photoresist 9 as a mask, anti-reflective coating 4 and upper interlayer insulating film 3b are etched, and etching is stopped at upper layer etching stopper film 18 as shown in FIG. 2C.

Trench 10 is thus formed. Here, because of the presence of upper layer etching stopper film 18, formation of a subtrench in the bottom portion of trench 10 can be suppressed. Preferably, upper layer etching stopper film 18 is constituted of a film of low dielectric constants such as SiC because capacity between interconnections is produced thereby.

Next, photoresist 9 and organic film 17 are removed with the same method as in Embodiment 1 as shown in FIG. 2D, anti-reflective coating 4 is removed thereafter by etching of the whole surface as shown in FIG. 2E, and etching stopper film 16 and upper layer etching stopper film 18 are selectively removed. Here, by forming upper layer etching stopper film 18, generation of a subtrench in the bottom portion of trench 10 can be suppressed.

Barrier layer 12 and second interconnection 13 are then formed in via hole 6 and trench 10 with the same method as in Embodiment 1, and the surface thereof is planarized. Through those steps described above, a dual damascene structure shown in FIG. 2F can be obtained.

According to the present Embodiment 2, in addition to the effects described in Embodiment 1, generation of a subtrench in the bottom portion of trench 10 can be suppressed. Therefore, a semiconductor device of higher reliability than in Embodiment 1 can be obtained.

### Embodiment 3

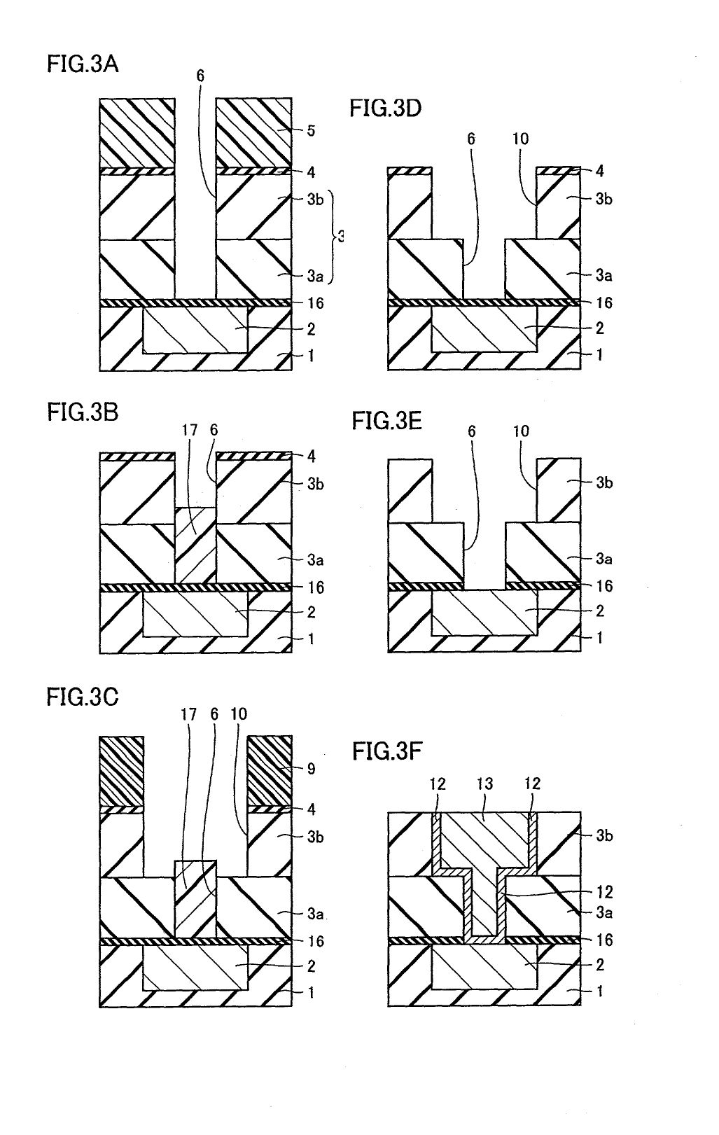

Next, Embodiment 3 of the present invention will be described with reference to FIGS. 3A to 3F. FIGS. 3A to 3F are cross-sectional views showing first to sixth steps in a manufacturing process of a semiconductor device in Embodiment 3.

In Embodiment 3, second interlayer insulating film 3 is constituted of a plurality of insulating films, and materials therefor are different. Other configurations are the same as in Embodiment 1.

As shown in FIG. 3A, structures up to etching stopper film 16 are formed with the same method as in Embodiment 1, and lower interlayer insulating film 3a and upper interlayer insulating film 3b are successively formed thereon with CVD and the like. A material of which etching rate is lower layer than that of upper interlayer insulating film 3b is selected for lower interlayer insulating film 3a.

Specifically, for example, when lower interlayer insulating film 3a is composed of USG (Undoped Silicate Glass), upper interlayer insulating film 3b is composed of FSG fluorinated Silicate Glass); and when lower interlayer insulating film 3a is composed of TEOS (Tetra Ethyl Ortho Silicate), upper interlayer insulating film 3b is composed of SiOC.

Anti-reflective coating 4 and photoresist 5 are formed on upper interlayer insulating film 3b with the same method as in Embodiment 1. Using photoresist 5 as a mask, etching is performed to form via hole 6 reaching etching stopper film 16, as shown in FIG. 3A.

Thereafter, as shown in FIG. 3B, with the same method as in Embodiment 1, organic film 17 is formed and photoresist 9 is formed on anti-reflective coating 4. Using photoresist 9 as a mask, anti-reflective coating 4 and upper interlayer insulating film 3b are etched, and etching is stopped at lower interlayer insulating film 3a as shown in FIG. 3C. Here, as lower interlayer insulating film 3a attains the same function as the etching stopper film, generation of a subtrench in the bottom portion of trench 10 can be suppressed.

Next, photoresist 9 and organic film 17 are removed with the same method as in Embodiment 1 as shown in FIG. 3D, and anti-reflective coating 4 and etching stopper film 16 on the first interconnection are removed thereafter by etching of the whole surface as shown in FIG. 3E. Here, as a material with a small etching rate has been selected for lower interlayer insulating film 3a, generation of a subtrench in the bottom portion of trench 10 can be suppressed.

Barrier layer 12 and second interconnection 13 are then formed in via hole 6 and trench 10 with the same method as in Embodiment 1, and the surface thereof is planarized. Through those steps described above, a dual damascene structure shown in FIG. 3F can be obtained.

According to Embodiment 3, in addition to the effects described in Embodiment 1, generation of a subtrench in the bottom portion of trench 10 can be suppressed. Therefore, a semiconductor device of higher reliability than in Embodiment 1 can be obtained.

### Embodiment 4

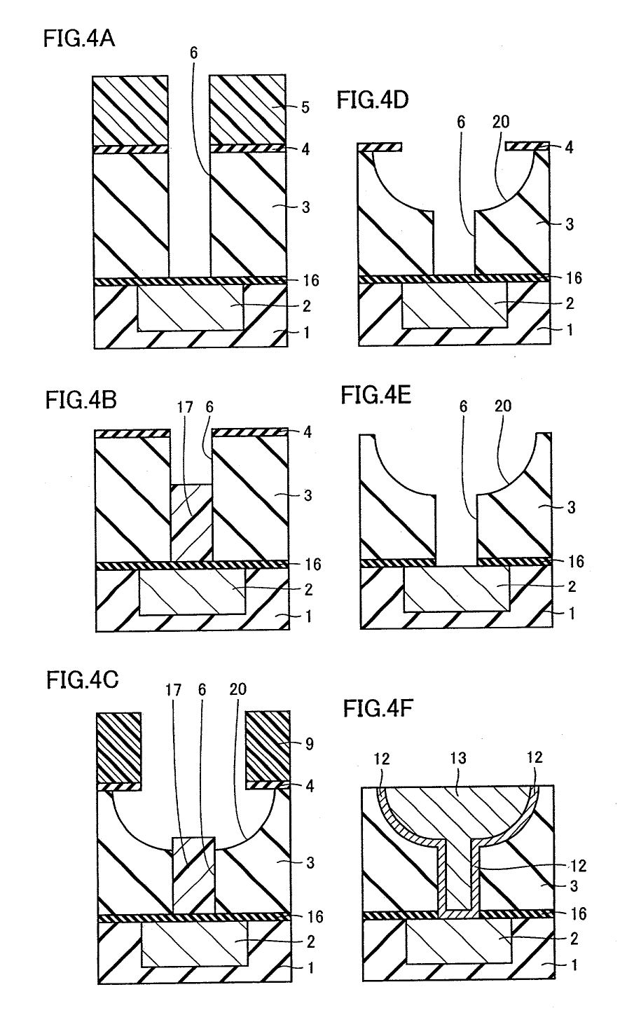

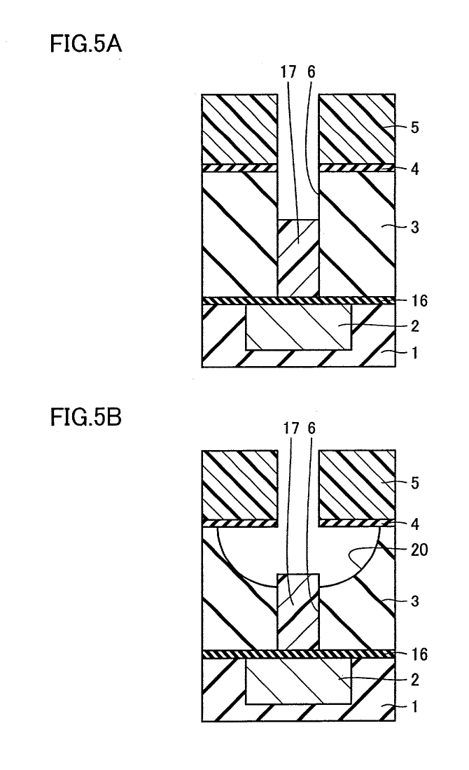

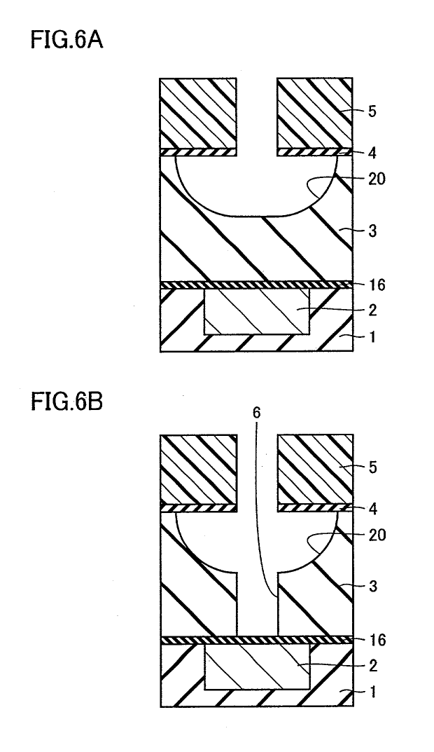

Next, Embodiment 4 of the present invention will be described with reference to FIGS. 4 to 6. FIGS. 4A to 4F are cross-sectional views showing first to sixth steps in a manufacturing process of a semiconductor device in Embodiment 4. FIGS. 5A and 5B are cross-sectional views showing characteristic steps of a first variation of the process shown in FIGS. 4A to 4F, and FIGS. 6A and 6B are cross-sectional views showing characteristic steps of a second variation of the process shown in FIGS. 4A to 4F.

Embodiment 4 is significantly characterized by isotropic etching when forming a trench. Thus, a trench having a wall surface gently inclined from the surface of second interlayer insulating film 3 toward via hole 6 can be formed, and formation of a subtrench on the bottom portion of the trench can be suppressed.

As shown in FIGS. 4A and 4B, structures up to organic film 17 are formed through the same steps as in Embodiment 1. As shown in FIG. 4C, photoresist 9 is then formed on anti-reflective coating 4, and isotropic etching is performed using photoresist 9 as a mask. Wet etching using such as HF+NH₄OH+H₂O₂ can be performed as the etching. By performing above etching, a trench 20 having a shape of upwardly widened opening can be formed.

Next, photoresist 9 and organic film 17 are removed with the same method as in Embodiment 1 as shown in FIG. 4D, and anti-reflective coating 4 and etching stopper film 16 on the first interconnection are removed thereafter by etching of the whole surface as shown in FIG. 4E. Here, as trench 20 has a semi-spheric shape (a bowl-like shape), formation of a subtrench can be suppressed.

Thereafter, barrier layer 12 and second interconnection 13 are formed in via hole 6 and trench 20 with the same method as in Embodiment 1, and the surface thereof is planarized. Through those steps described above, a dual damascene structure shown in FIG. 4F can be obtained.

In Embodiment 4, trench 20 has a shape like a bowl. Therefore, in addition to the effects described in Embodiment 1, formation of a subtrench in the bottom portion of trench 20 can be suppressed, and moreover, embedment property of barrier layer 12 and second interconnection 13 can be improved. Thus, a semiconductor device of higher reliability can be obtained.

Next, a first variation of the foregoing process will be described with reference to FIGS. 5A and 5B.

In the present variation, as shown in FIG. 5A, while photoresist 5 is left, organic film 17 is formed with the same method as in Embodiment 1, and isotropic etching is performed using photoresist 5 as a mask. Accordingly, trench 20 is formed as shown in FIG. 5B. Steps thereafter are the same as in above-described Embodiment 4.

The above isotropic etching may be performed by dry etching under the pressure of not smaller than 10 mTorr (1.33 Pa) and not larger than 200 mTorr (26.6 Pa) using CF₄+O₂+Ar gas plasma, for example, or by wet etching using HF+NH₄OH+H₂O₂, for example.

In this case, photoresist 9 need not be formed, and the step of forming thereof can be omitted, thus to simplify the process. When dry etching is adopted, for example, there is no possibility of permeation of wet etchant between anti-reflective coating 4 and second interlayer insulating film 3, and dimension control will be easy even in isotropic etching. On the other hand, when wet etching is adopted, difference of selective etching rate with respect to underlying material will be large, making an organic protective film in a via hole unnecessary.

Next, a second variation of the foregoing process will be described with reference to FIGS. 6A and 6B.

In the present variation, as shown in FIG. 6A, isotropic etching is performed using photoresist 5 as a mask. Thereafter, using photoresist 5 as a mask, anisotropic etching is performed to form via hole 6. Photoresist 5 is then removed with O₂ plasma and the like. Steps thereafter are the same as in above-described Embodiment 4.

With this method, the step of embedding organic film 17 in via hole 6 can be omitted, to simplify the process.

### Embodiment 5

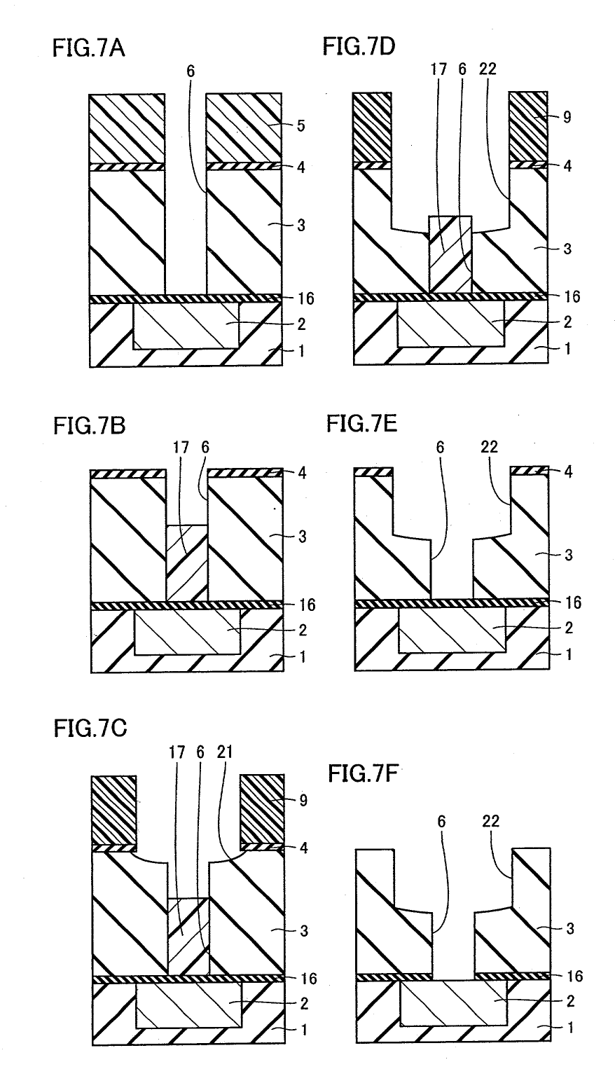

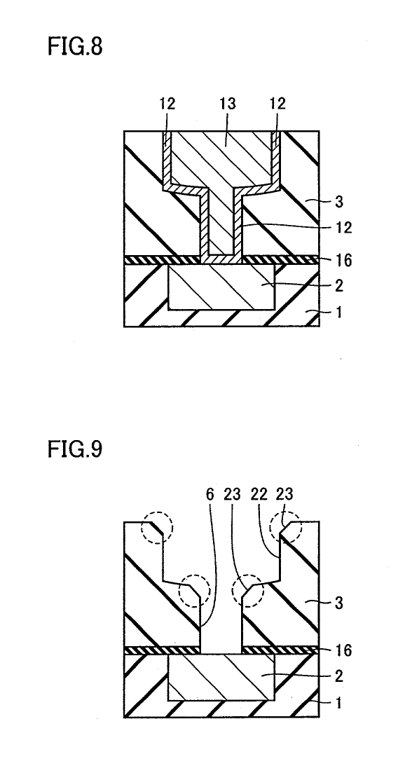

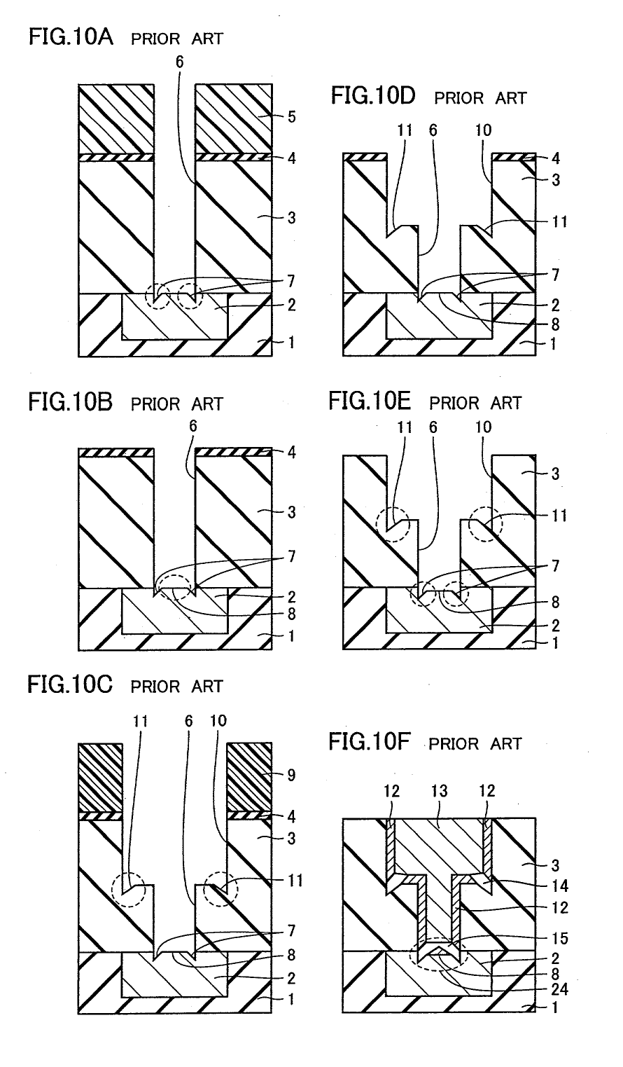

Next, Embodiment 5 of the present invention will be described with reference to FIGS. 7 to 9. FIGS. 7A to 7F are cross-sectional views showing first to sixth steps of a manufacturing process of a semiconductor device in Embodiment 5. FIG. 8 is a cross-sectional view showing a seventh step in the manufacturing process of the semiconductor device in Embodiment 5, and showing a semiconductor device in Embodiment 5. FIG. 9 is a cross-sectional view showing a characteristic step of a variation of the process shown in FIGS. 7A to 7F.

Embodiment 5 is characterized by isotropic and anisotropic etching to form a trench 22. In this case as well, trench 22 can have a bottom surface gently inclined, and generation of a subtrench can be suppressed.

As shown in FIGS. 7A to 7C, structures up to photoresist 9 are formed with the same method as in Embodiment 1. Using photoresist 9 as a mask, isotropic etching is performed to form a shallow trench 21. Trench 21 has a bottom surface gently inclined as shown in FIG. 7C.

The above isotropic etching may be performed by dry etching under the pressure not smaller than 10 mTorr (1.33 Pa) and not larger than 200 mTorr (26.6 Pa) using C₅F₈+O₂+Ar gas plasma, for example, or by wet etching using HF+NH₄OH+H₂O₂, for example.

Next, as shown in FIG. 7D, anisotropic etching is performed using photoresist 9 as a mask. The anisotropic etching can be performed by dry etching under the pressure not smaller than 0.7 mTorr (0.093 Pa) and not larger than 100 mTorr (13.3 Pa) using C₅F₈+O₂+Ar gas plasma, for example.

Trench 22 is formed through above etching. Here, as shallow trench 21 has been already formed, the bottom surface of trench 22 is gently inclined, reflecting the shape of the bottom surface of trench 21. Thus, formation of a subtrench in the bottom portion of trench 22 can be suppressed.

Next, photoresist 9 and organic film 17 are removed with the same method as in Embodiment 1 as shown in FIG. 7E, and anti-reflective coating 4 and etching stopper film 16 on the first interconnection are removed thereafter by etching of the whole surface as shown in FIG. 7F. Here, as the bottom surface of trench 22 is gently inclined and the shape thereof is semi-spheric, formation of a subtrench can be suppressed.

Thereafter, barrier layer 12 and second interconnection 13 are formed in via hole 6 and trench 22 with the same method as in Embodiment 1, and the surface thereof is planarized. Through those steps described above, a dual damascene structure shown in FIG. 8 can be obtained.

In Embodiment 5, trench 22 has a bottom surface gently inclined. Therefore, in addition to the effects described in Embodiment 1, formation of a subtrench in the bottom portion of trench 22 can be suppressed, and embedment property of barrier layer 12 and second interconnection 13 can be improved. Thus, a semiconductor device of higher reliability can be obtained.

Next, a variation of Embodiment 5 will be described with reference to FIG. 9.

As shown in FIG. 9, in a process of etching of the whole surface shown in FIG. 7F, sputtering effect is strengthened by setting the pressure for etching to be 100 mTorr (13.3 Pa) or smaller, so that a tapered portion (a facet) 23 may be formed at upper end portions of wall surfaces of via hole 6 and trench 22. Thus, embedment property of second interconnection 13 can be further improved.

According to the present invention, since an etching stopper film is formed on the bottom of a via hole, exposure of a first interconnection at the bottom of the via hole can be prevented until the etching stopper film on the first interconnection is removed, and formation of a subtrench on the bottom of the via hole can be avoided. The height of a protective film from the bottom of the via hole can also be adjusted easily. In addition, lowering of dimension accuracy of the via hole can be suppressed because an anti-reflective coating is formed on a second interlayer insulating film. Thus, while suppressing generation of a subtrench and alteration of the surface of the first interconnection, a protective film can be formed on the bottom of the via hole in a stable manner, and lowering of dimension accuracy of the via hole can be suppressed.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A method of manufacturing a semiconductor device, comprising the steps of:
forming a first interconnection within a first interlayer insulating film;
forming an etching stopper film on said first interconnection;
successively forming a second interlayer insulating film and an anti-reflective coating on said etching stopper film;
forming a via hole penetrating said second interlayer insulating film and said anti-reflective coating to reach said etching stopper film;
forming a protective film in said via hole;
forming a trench reaching said protective film in said second interlayer insulating film;
exposing a portion of a surface of said first interconnection by removing said anti-reflective coating and said etching stopper film on a bottom portion of said via hole; and
forming a second interconnection within said trench and said via hole.

2. The method of manufacturing a semiconductor device according to claim 1, wherein
said second interlayer insulating film has an upper interlayer insulating film and a lower interlayer insulating film; and
the step of forming said second interlayer insulating film includes the step of forming said upper interlayer insulating film on said lower interlayer insulating film.

3. The method of manufacturing a semiconductor device according to claim 2, wherein
an upper layer etching stopper film is provided between said upper interlayer insulating film and said lower interlayer insulating film;
the step of forming said second interlayer insulating film includes the step of forming said upper interlayer insulating film on said lower interlayer insulating film with said upper layer etching stopper film interposed; and
the step of forming said trench includes the step of stopping etching at said upper layer etching stopper film.

4. The method of manufacturing a semiconductor device according to claim 2, wherein
said upper interlayer insulating film and said lower interlayer insulating film are composed of different materials; and
the step of forming said trench includes the step of forming said trench in said upper interlayer insulating film by stopping etching at said lower interlayer insulating film.

5. The method of manufacturing a semiconductor device according to claim 1, wherein
the step of forming said trench includes the step of isotropically etching said second interlayer insulating film.

6. The method of manufacturing a semiconductor device according to claim 5, wherein
said isotropic etching is performed by dry etching under a pressure not smaller than 1.33 Pa and not larger than 26.6 Pa.

7. The method of manufacturing a semiconductor device according to claim 5, wherein
the step of forming said trench includes the step of anisotropic etching after said isotropic etching.

8. The method of manufacturing a semiconductor device according to claim 1, wherein
the step of forming said second interconnection includes the step of forming a tapered portion at upper end corner portions of said trench and said via hole.

9. The method of manufacturing a semiconductor device according to claim 1, wherein
the step of forming said protective film includes the steps of applying a photoresist to a whole surface after said via hole is formed, and
leaving said photoresist in said via hole by etching said photoresist.

10. The method of manufacturing a semiconductor device according to claim 1, wherein
the step of forming said protective film includes the steps of applying a photoresist to a whole surface after said via hole is formed, and
exposing and developing said photoresist and leaving the photoresist in said via hole.

11. A method of manufacturing a semiconductor device comprising the steps of:
forming a first interconnection within a first interlayer insulating film;
forming an etching stopper film on said first interconnection;
successively forming a second interlayer insulating film and an anti-reflective coating on said etching stopper film;
forming a trench by isotropically etching said second interlayer insulating film;
forming a via hole below said trench to reach said etching stopper film;
exposing a portion of a surface of said first interconnection by removing said anti-reflective coating and said etching stopper film on a bottom portion of said via hole; and
forming a second interconnection within said trench and said via hole.

12. A semiconductor device having an interconnection structure manufactured with the method of manufacturing a semiconductor device according to claim 1.
